(19) United States
(12) Patent Application Publication
(10) Pub. No.: US 2026/0150712 A1
(43) Pub. Date: May 28, 2026

(54) SEMICONDUCTOR DEVICE

(71) Applicant: FUJI ELECTRIC CO., LTD., Kawasaki-shi (JP)

(72) Inventors: Haruyasu SATO, Matsumoto-city (JP); Takahide TANAKA, Matsumoto-city (JP)

(73) Assignee: FUJI ELECTRIC CO., LTD., Kawasaki-shi (JP)

(21) Appl. No.: 19/319,440

(22) Filed: Sep. 4, 2025

(30) Foreign Application Priority Data
Nov. 28, 2024 (JP) 2024-207546

(51) Int. Cl. H01L 23/495; H01L 23/00; H01L 25/065; H10D 80/30

(52) U.S. Cl. CPC H10W 70/442; H10D 80/30; H10W 70/417; H10W 90/00; H10W 72/354; H10W 72/5453; H10W 72/884; H10W 90/736; H10W 90/753; H10W 90/756

(57) ABSTRACT

A semiconductor device includes: a GND reference circuit based on a GND potential and a floating reference circuit based on a potential higher than the GND potential; a lead frame; a first semiconductor substrate arranged on the lead frame and provided with the GND reference circuit; and a second semiconductor substrate arranged on the lead frame and provided with the floating reference circuit, wherein either the first semiconductor substrate or the second semiconductor substrate is arranged on the lead frame with an insulating material interposed.

### CROSS-REFERENCE TO RELATED APPLICATION

This application claims benefit of priority under 35 USC 119 based on Japanese Patent Application No. 2024-207546 filed on Nov. 28, 2024, the entire contents of which are incorporated by reference herein.

### BACKGROUND OF THE INVENTION

### 1. Field of the Invention

The present disclosure relates to semiconductor devices.

### 2. Description of the Related Art

JP2001-237381A discloses a semiconductor device including a GND reference circuit and a floating reference circuit provided in different semiconductor substrates in order to avoid wrong operations derived from a parasitic element. JP2010-154721A discloses a semiconductor device including a GND reference circuit provided in a first substrate, and a floating reference circuit provided in a second substrate that is an SOI substrate, in which the first substrate and the second substrate are installed on a common lead frame. JP2018-191011A discloses an intelligent power module (IPM).

The configuration of the semiconductor device disclosed in JP2001-237381A is required to arrange the respective substrates provided with the GND reference circuit and the floating reference circuit on the different lead frames, which restricts flexibility of design of a pattern usable for the lead frames.

While the semiconductor device disclosed in JP2010-154721A has the configuration in which the respective substrates provided with the GND reference circuit and the floating reference circuit are arranged on the same lead frame, the SOI substrate requires high-priced material, leading to an increase in cost accordingly.

### SUMMARY OF THE INVENTION

In view of the foregoing problems, the present disclosure provides a semiconductor device having a configuration capable of avoiding wrong operations derived from a parasitic element while contributing to a reduction in cost.

An aspect of the present disclosure inheres in a semiconductor device including:
a GND reference circuit based on a GND potential and a floating reference circuit based on a potential higher than the GND potential; a lead frame; a first semiconductor substrate arranged on the lead frame and provided with the GND reference circuit; and a second semiconductor substrate arranged on the lead frame and provided with the floating reference circuit, wherein either the first semiconductor substrate or the second semiconductor substrate is arranged on the lead frame with an insulating material interposed.

### BRIEF DESCRIPTION OF THE DRAWINGS

FIG. 1 is a circuit diagram illustrating a semiconductor device according to a first embodiment;

FIG. 2 is a plan view illustrating the semiconductor device according to the first embodiment;

FIG. 3 is a cross-sectional view illustrating a first substrate according to the first embodiment;

FIG. 4 is a cross-sectional view taken along line A-A′ in FIG. 2;

FIG. 5 is another plan view illustrating the semiconductor device according to the first embodiment;

FIG. 6 is a plan view illustrating a semiconductor device of a comparative example;

FIG. 7 is a cross-sectional view illustrating the semiconductor device of the comparative example;

FIG. 8 is a cross-sectional view illustrating a semiconductor device according to a second embodiment;

FIG. 9 is a circuit diagram illustrating a semiconductor device according to a third embodiment;

FIG. 10 is a plan view illustrating the semiconductor device according to the third embodiment;

FIG. 11 is a plan view illustrating a semiconductor device according to a fourth embodiment; and

FIG. 12 is a cross-sectional view illustrating a semiconductor device according to a fifth embodiment.

### DETAILED DESCRIPTION

With reference to the drawings, first to fifth embodiments of the present disclosure will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first to fifth embodiments described below merely illustrate schematically devices and methods for specifying and giving shapes to the technical idea of the present disclosure, and the span of the technical idea is not limited to materials, shapes, structures, and relative positions of elements described herein.

In the specification, a “carrier supply region” means a semiconductor region which supplies majority carriers as a main current. The carrier supply region is assigned to a semiconductor region which will be a source region in a field-effect transistor (FET) or a static induction transistor (SIT), an emitter region in an insulated-gate bipolar transistor (IGBT), and an anode region in a diode, a static induction (SI) thyristor or a gate turn-off (GTO) thyristor. A “carrier reception region” means a semiconductor region which receive the majority carriers as the main current. The carrier reception region is assigned to a semiconductor region which will be the drain region in the FET or the SIT, the collector region in the IGBT, and the cathode region in the diode, SI thyristor or GTO thyristor.

In the specification, definitions of directions such as an up-and-down direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

In the specification, there is exemplified a case where a first conductivity-type is a p-type and a second conductivity-type is an n-type. Further, a semiconductor region denoted by the symbol “n” or “p” attached with “+” indicates that such semiconductor region has a relatively high impurity concentration as compared to a semiconductor region denoted by the symbol “n” or “p” without “+”. A semiconductor region denoted by the symbol “n” or “p” attached with “−” indicates that such semiconductor region has a relatively low impurity concentration as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration. Moreover, the members and the regions that are limited by adding “first conductivity-type”, “second conductivity-type”, “n-type” and “p-type” in the following description indicate the members and the regions formed of semiconductor materials without particular obvious limitations. Further, in the appended claims, the term “n-type” as used herein encompasses any of n-type, n⁻-type, and n⁺-type, and the term “p-type” encompasses any of p-type, p⁻-type, and p⁺-type.

### First Embodiment

### Circuit of Semiconductor Device

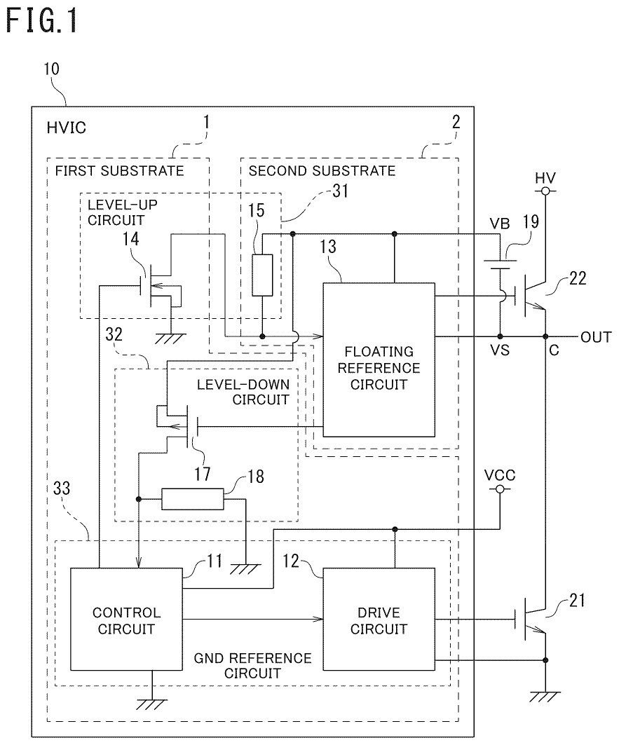

A semiconductor device according to a first embodiment includes a high voltage integrated circuit (HVIC) 10, and power gate-driving switching elements 21 and 22 that are a target to be driven by the HVIC 10, as illustrated in FIG. 1. The semiconductor device according to the first embodiment may be an intelligent power module (IPM). The HVIC 10 and the switching elements 21 and 22 are installed in the same package. The semiconductor device according to the first embodiment may have a configuration including the HVIC 10 without the switching elements 21 and 22 included. Alternatively, the semiconductor device according to the first embodiment may have a configuration equipped with both of the HVIC 10 and the switching elements 21 and 22.

The switching element 21 on the low-potential side (the low-potential side switching element) and the switching element 22 on the high-potential side (the high-potential side switching element) are connected in series to implement a half-bridge circuit. While FIG. 1 illustrates the case in which the low-potential side switching element 21 and the high-potential side switching element 22 are each an insulated gate bipolar transistor (IGBT), the respective elements may be any other switching element such as a metal-oxide-semiconductor field-effect transistor (MOSFET). Although not illustrated in FIG. 1, a free-wheeling diode (FWD) may be connected in antiparallel to the IGBT or the MOSFET each implementing the low-potential side switching element 21 and the high-potential side switching element 22.

A HV potential on a high-potential side of a high-voltage power supply (not illustrated) is connected to a drain of the high-potential side switching element 22. A ground potential (a GND potential) on a low-potential side is connected to a source of the low-potential side switching element 21. An intermediate potential C is defined as a VS potential, which is a floating potential at a connection point between a source of the high-potential side switching element 22 and a drain of the low-potential side switching element 21. A load (not illustrated) such as a three-phase motor can be connected to the connection point between the source of the high-potential side switching element 22 and the drain of the low-potential side switching element 21, so that a signal OUT corresponding to the intermediate potential C is output to the load.

The HVIC 10 includes a GND reference circuit 33 serving as a low-potential side circuit (a low-side circuit) and a floating reference circuit 13 serving as a high-potential side circuit (a high-side circuit). The GND reference circuit 33 operates with the GND potential as a reference potential and with a VCC potential higher by about 15 volts than the GND potential as a power supply potential. The floating reference circuit 13 operates with the VS potential higher than the GND potential as a reference potential and with a VB potential higher than the VS potential as a power supply potential.

The VB potential is a maximum potential applied to the HVIC 10, and is kept higher than the VS potential by about 15 volts in a normal operation not influenced by noise. The VS potential repeats a rise and a drop between the HV potential (about 100 to 400 volts, for example) on the high-potential side of the high voltage power supply and the GND potential on the low-potential side, and fluctuates between zero to several hundreds of volts when the high-potential side switching element 22 and the low-potential side switching element 21 are complementarily turned on and off. The VS potential can fall below zero.

The GND reference circuit 33 and the floating reference circuit 13 are electrically connected to each other via a level-shift circuit (31, 32). The level-shift circuit (31, 32) executes the transmission of signals between the GND reference circuit 33 and the floating reference circuit 13. The level-shift circuit (31, 32) includes a level-up circuit 31 and a level-down circuit 32. The level-up circuit 31 outputs a signal from the GND reference circuit 33 to the floating reference circuit 13. The level-down circuit 32 outputs a signal from the floating reference circuit 13 to the GND reference circuit 33.

The GND reference circuit 33 includes a control circuit 11 and a drive circuit 12. An external microcomputer (not illustrated) is connected to the control circuit 11. The control circuit 11 outputs, to the drive circuit 12, a control signal based on the GND potential for controlling an ON/OFF state of a gate of the low-potential side switching element 21 in accordance with an input signal from the microcomputer. The control circuit 11 outputs, to the floating reference circuit 13 via the level-up circuit 31, a control signal based on the GND potential for controlling an ON/OFF state of a gate of the high-potential side switching element 22 in accordance with an input signal from the microcomputer. The GND reference circuit 33 does not necessarily include the drive circuit 12. The GND reference circuit 33 may also have a configuration including only a part of the control circuit 11.

The control circuit 11 may have a function that outputs, to the microcomputer, an alarm signal or the like input from the floating reference circuit 13 via the level-down circuit 32 or outputs a control signal for turning OFF the low-potential side switching element 21 or the high-potential side switching element 22 in accordance with the alarm signal or the like.

The drive circuit 12 applies, to the gate of the low-potential side switching element 21, a drive signal for driving the low-potential side switching element 21 in accordance with the control signal from the control circuit 11.

The level-up circuit 31 converts the control signal based on the GND potential from the control circuit 11 of the GND reference circuit 33 into a control signal based on the VS potential, and outputs the converted control signal to the floating reference circuit 13. The level-up circuit 31 includes a level-shift element (a level shifter) 14 and a resistor (a level-shift resistor) 15. The level shifter 14 is implemented by a high-voltage n-channel MOSFET (a HVNMOS), for example. The control signal based on the GND potential from the GND reference circuit 33 is applied to a gate of the level shifter 14. The GND potential is connected to a source of the level shifter 14. The floating reference circuit 13 and one end of the level-shift resistor 15 are connected to a drain of the level shifter 14. The VB potential on the positive electrode side of a power supply 19 is connected to the other end of the level-shift resistor 15.

The level-down circuit 32 converts the signal based on the VS potential from the floating reference circuit 13 into a signal based on the GND potential, and outputs the converted signal to the control circuit 11 of the GND reference circuit 33. The level-down circuit 32 includes a level-shift element (a level shifter) 17 and a resistor (a level-shift resistor) 18. The level shifter 17 is implemented by a high-voltage p-channel MOSFET (a HVPMOS), for example. The signal based on the VS potential from the floating reference circuit 13 is applied to a gate of the level shifter 17. The other end of the level-shift resistor 15 and the VB potential on the positive electrode side of the power supply 19 are connected to a source of the level shifter 17. The control circuit 11 of the GND reference circuit 33 and one end of the level-shift resistor 18 are connected to a drain of the level shifter 17. The GND potential is connected to the other end of the level-shift resistor 18. The provision of the level-down circuit 32 in this embodiment is optional.

The floating reference circuit 13 includes, at the output stage, a CMOS circuit implemented by an n-channel MOSFET and a p-channel MOSFET, for example. The floating reference circuit 13 outputs, to the gate of the high-potential side switching element 22, a drive signal for driving the high-potential side switching element 22 in accordance with the control signal based on the VS potential from the level-up circuit 31. The floating reference circuit 13 may detect a temperature or an overcurrent, for example, so as to output an alarm signal or the like to the control circuit 11 via the level-down circuit 32 according to the detected information.

As schematically indicated by the broken line in FIG. 1, the HVIC 10 is provided in a first semiconductor substrate (a first substrate) 1 and a second semiconductor substrate (a second substrate) 2. The first substrate 1 is provided with the GND reference circuit 33, the level shifter 14 of the level-up circuit 31, and the level shifter 17 and the level-shift resistor 18 of the level-down circuit 32. The second substrate 2 is provided with the level-shift resistor 15 of the level-up circuit 31, and the floating reference circuit 13.

The level shifter 14 of the level-up circuit 31 may be provided in the second substrate 2, instead of the first substrate 1. The level shifter 17 may be provided in the second substrate 2, instead of the first substrate 1.

### Configuration of Semiconductor Device

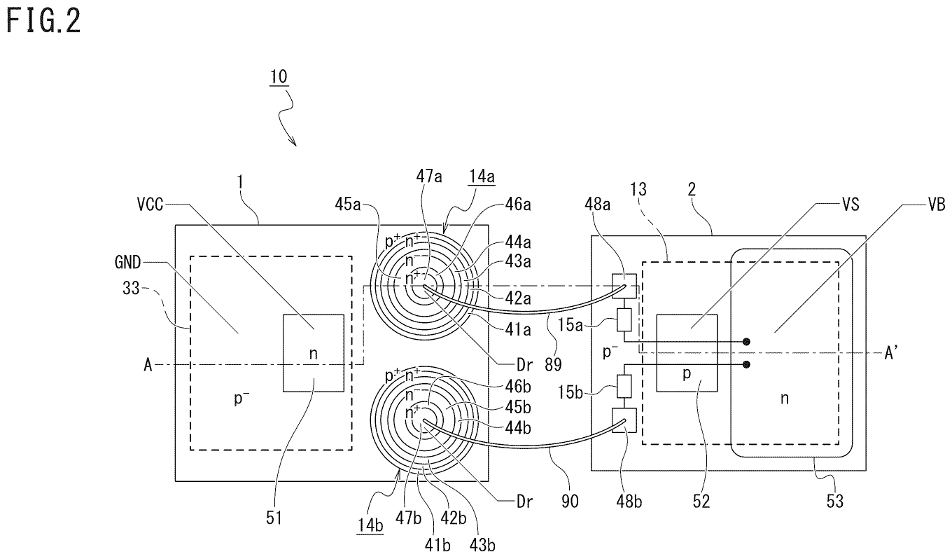

FIG. 2 is a planar layout of the HVIC 10. As illustrated in FIG. 2, the HVIC 10 includes a first substrate 1 of a first conductivity-type (p⁻-type) and a second substrate 2 of the first conductivity-type (p⁻-type). The first substrate 1 and the second substrate 2 are each a silicon (Si) substrate, for example. The first substrate 1 and the second substrate 2 may each be a semiconductor substrate including wide bandgap semiconductor having a wider band gap than Si, such as silicon carbide (SiC), a gallium nitride (GaN), a gallium oxide (Ga₂O₃), gallium arsenide (GaAs), and diamond (C).

The first substrate 1 and the second substrate 2 may each include a semiconductor substrate, and an epitaxial growth layer grown on the semiconductor substrate. The epitaxial growth layer in this case may have substantially the same impurity concentration as the semiconductor substrate, or may have an impurity concentration that is either higher than or lower than that of the semiconductor substrate.

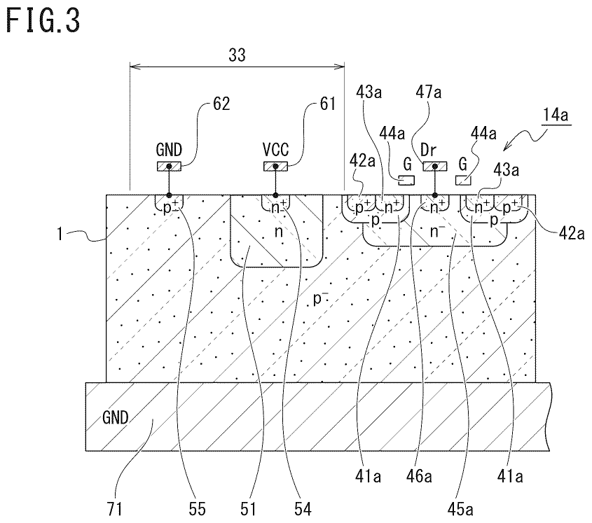

FIG. 3 is a cross-sectional view illustrating the first substrate 1 on the left side of the cross section taken along line A-A′ in FIG. 2. As illustrated in FIG. 3, the first substrate 1 is provided on a lead frame 71 to which the GND potential is applied. As illustrated in FIG. 2 and FIG. 3, a well region 51 of a second conductivity-type (n-type) is provided on the top surface side of the first substrate 1. The well region 51 has a substantially rectangular planar pattern. The planar pattern and the arranged position of the well region 51 can be changed as appropriate.

As illustrated in FIG. 3, a pickup region (a contact region) 54 of n⁺-type having a higher impurity concentration than the well region 51 is provided on the top surface side of the n-type well region 51. A VCC electrode 61 is electrically connected to the pickup region 54. The VCC potential that is the power supply potential of the GND reference circuit 33 is applied to the VCC electrode 61. FIG. 2 omits the illustration of the VCC electrode 61 and the pickup region 54 illustrated in FIG. 3. The planar pattern and the arranged position of each of the VCC electrode 61 and the pickup region 54 can be changed as appropriate.

A pickup region (a contact region) 55 of p⁺-type having a higher impurity concentration than the first substrate 1 is provided on the top surface side of the first substrate 1. A GND electrode 62 is electrically connected to the pickup region 55. The GND potential that is the reference potential of the GND reference circuit 33 is applied to the GND electrode 62. FIG. 2 omits the illustration of the GND electrode 62 and the pickup region 55 illustrated in FIG. 3. The planar pattern and the arranged position of each of the GND electrode 62 and the pickup region 55 can be changed as appropriate.

A region of the first substrate 1 including the pickup region 55 and the well region 51 is provided with the GND reference circuit 33. FIG. 2 and FIG. 3 each omit the illustration of the respective elements included in the GND reference circuit 33.

A manufacturing method for the HVIC 10 is broadly divided into a wire-bonding method (a WB method) and a self-shielding method (an SS method) depending on how to form the respective level shifters 14 and 17. The WB method is to form the respective level shifters 14 and 17 in the regions different from a HVJT region so as to connect the respective level shifters 14 and 17 to the floating reference circuit 13 by wire bonding with metal wires. The SS method is to form the respective level shifters 14 and 17 and the HVJT integrally with each other. The semiconductor device according to the first embodiment is illustrated with a case of forming the respective level shifters 14 and 17 by the WB method.

As illustrated in FIG. 2, the first substrate 1 includes two level shifters 14a and 14b obtained by the WB method. The respective level shifters 14a and 14b correspond to the level shifter 14 illustrated in FIG. 1. FIG. 2 omits the illustration of the level shifter 17 illustrated in FIG. 1. The level shifter 17 illustrated in FIG. 1 is described below. The level shifters 14a and 14b each have a substantially circular planar pattern. The level shifters 14a and 14b are each implemented by a HVNMOS.

As illustrated in FIG. 2 and FIG. 3, the level shifter 14a includes a base region 41a of p-type, a pickup region (a contact region) 42a of p⁺-type, a carrier supply region (a source region) 43a of n⁺-type, a gate electrode 44a, a drift region 45a of n⁻-type, and a carrier reception region (a drain region) 46a of n⁺-type. The base region 41a has a loop-shaped planar pattern. The pickup region 42a and the source region 43a are arranged inside the base region 41a so as to have a loop-shaped planar pattern. The drift region 45a is arranged in contact with the base region 41a, and has a circular planar pattern. The drift region 45a may have a greater depth than the well region 51.

The gate electrode 44a is located, via a gate insulating film (not illustrated), above the loop-shaped p-type base region 41a interposed between the source region 43a and the drift region 45a. The drain region 46a is provided on the top surface side of the drift region 45a, and has a circular planar pattern. A drain electrode 47a is provided on the top surface side of the drain region 46a. A pad 48a in the second substrate 2 is connected to the drain electrode 47a via a metal wire 89.

As illustrated in FIG. 2, the level shifter 14b includes a base region 41b of p-type, a pickup region (a contact region) 42b of p⁺-type, a carrier supply region (a source region) 43b of n⁺-type, a gate electrode 44b, a drift region 45b of n⁻-type, and a carrier reception region (a drain region) 46b of n⁺-type. The base region 41b has a loop-shaped planar pattern. The pickup region 42b and the source region 43b are arranged inside the base region 41b so as to have a loop-shaped planar pattern. The drift region 45b is arranged in contact with the base region 41b, and has a circular planar pattern. The drift region 45b may have a greater depth than the well region 51.

The gate electrode 44b is located, via a gate insulating film (not illustrated), above the loop-shaped p-type base region 41b interposed between the source region 43b and the drift region 45b. The drain region 46b is provided on the top surface side of the drift region 45b, and has a circular planar pattern. A drain electrode 47b is provided on the top surface side of the drain region 46b. A pad 48b in the second substrate 2 is connected to the drain electrode 47b via a metal wire 90. The level shifter 14b has the cross-sectional structure common to that of the level shifter 14a illustrated in FIG. 3.

As illustrated on the right side in FIG. 2, the second substrate 2 is located separately from the first substrate 1. A well region 53 of n-type is provided on the top surface side of the second substrate 2. The well region 53 has a substantially rectangular planar pattern. The planar pattern and the arranged position of the well region 53 can be changed as appropriate. The VB potential that is the power supply potential of the floating reference circuit 13 is applied to the well region 53.

A well region 52 of p-type is provided on the top surface side of the second substrate 2 separately from the well region 53. The well region 52 has a substantially rectangular planar pattern. The planar pattern and the arranged position of the well region 52 can be changed as appropriate. The VS potential that is the reference potential of the floating reference circuit 13 is applied to the well region 52.

A region of the first substrate 2 including the well region 53 and the well region 52 is provided with the floating reference circuit 13. FIG. 2 omits the illustration of the respective elements included in the floating reference circuit 13.

The pads 48a and 48b are provided in the second substrate 2 on the side opposed to the first substrate 1. The pad 48a is electrically connected to one end of a level-shift resistor 15a. The other end of the level-shift resistor 15a is connected to the VB potential. The pad 48b is electrically connected to one end of a level-shift resistor 15b. The other end of the level-shift resistor 15b is connected to the VB potential. The respective level-shift resistors 15a and 15b correspond to the level-shift resistor 15 illustrated in FIG. 1.

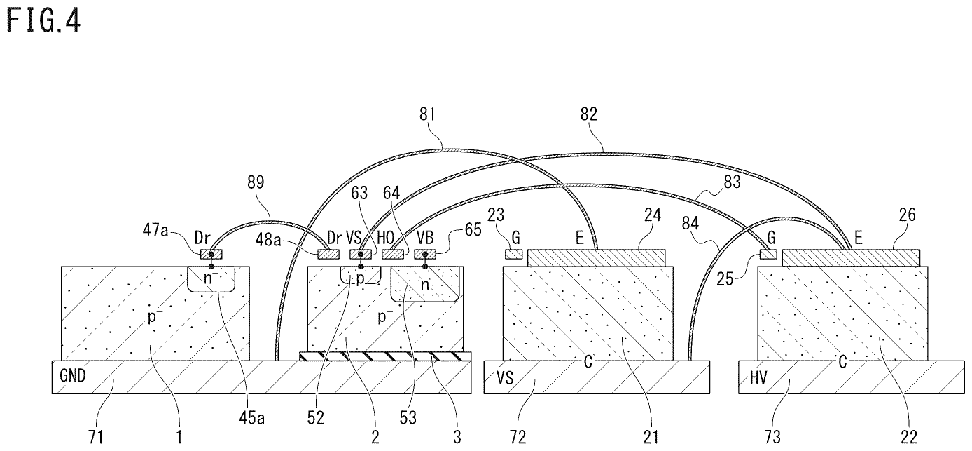

FIG. 4 is a cross-sectional view including a region taken along line A-A′ in FIG. 2. FIG. 4 illustrates the low-potential side switching element 21 and the high-potential side switching element 22, in addition to the first substrate 1 and the second substrate 2. FIG. 4 schematically indicates the respective emitter electrodes 24 and 26 by the sign “E”, indicates the respective gate electrodes 23 and 25 by the sign “G”, and indicates the collector electrodes (not illustrated) by the sign “C” included in the low-potential side switching element 21 and the high-potential side switching element 22.

As illustrated in FIG. 4, the first substrate 1 and the second substrate 2 are located (installed) on the common lead frame 71 to which the GND potential is applied. The first substrate 1 may be electrically connected to the lead frame 71 so as to be fixed to the GND potential. The bottom surface of the first substrate 1 may be provided on the lead frame 71 via a conductive adhesive. The bottom surface side of the first substrate 1 may be provided with an electrode so as to be provided on the lead frame 71 via conductive material such as solder, sinter material such as silver paste, or a conductive adhesive. FIG. 4 only illustrates the n⁻-type drift region 45a provided on the top surface side of the first substrate 1, while omitting the other diffusing regions in the first substrate 1 illustrated in FIG. 2 and FIG. 3.

The second substrate 2 is provided on the lead frame 71 with an insulating material 3 interposed. The second substrate 2 may be bonded to the lead frame 71 with the insulating material 3. The second substrate 2 and the lead frame 71 are insulated by the insulating material 3. The bottom surface side of the second substrate 2 may be provided with an electrode so as to be in contact with the insulating material 3. The insulating material 3 is resin paste or a die attach film (a DAF sheet). The first substrate 1 may be provided on the lead frame 71 with an insulating material similar to the insulating material 3 interposed.

As illustrated in FIG. 4, a VS electrode 63 electrically connected to the well region 52 is provided on the top surface side of the second substrate 2. A HO electrode 64 is a provided on the top surface side of the second substrate 2. The HO electrode 64 is connected to an output of a CMOS circuit (not illustrated) provided in the floating reference circuit 13. A VB electrode 65 electrically connected to the well region 53 is provided on the top surface side of the second substrate 2.

The low-potential side switching element 21 is provided on a lead frame 72 to which the VS potential is applied. The low-potential side switching element 21 is provided with a gate electrode 23 and an emitter electrode 24 on the top surface side, and provided with the collector electrode (not illustrated) on the bottom surface side. The emitter electrode 24 of the low-potential side switching element 21 is electrically connected to the lead frame 71 via a metal wire 81.

The high-potential side switching element 22 is provided on a lead frame 73 to which the HV potential is applied. The high-potential side switching element 22 is provided with a gate electrode 25 and an emitter electrode 26 on the top surface side, and the collector electrode (not illustrated) on the bottom surface side. The gate electrode 25 of the high-potential side switching element 22 is electrically connected to the HO electrode 64 via a metal wire 83. The emitter electrode 26 of the high-potential side switching element 22 is electrically connected to the VS electrode 63 via a metal wire 82, and is electrically connected to the lead frame 72 via a metal wire 84.

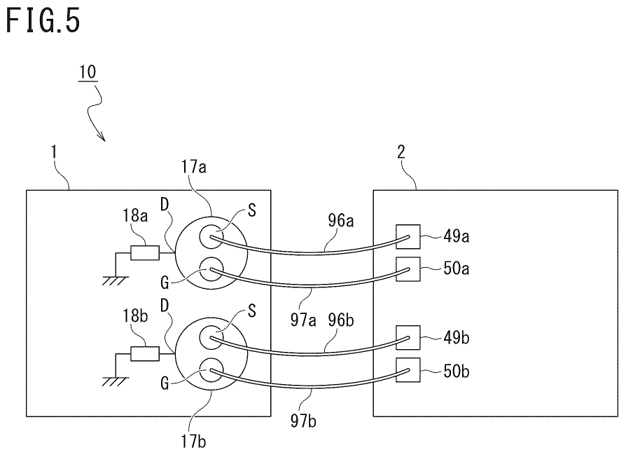

FIG. 5 is a planar layout of the HVIC 10, illustrating the level shifters 17a and 17b and the level-shift resistors 18a and 18b of the level-down circuit 32, while omitting the illustration of the level shifters 14a and 14b and the level-shift resistors 15a and 15b of the level-up circuit 31 illustrated in FIG. 2. The respective level shifters 17a and 17b correspond to the level shifter 17 illustrated in FIG. 1, and the respective level-shift resistors 18a and 18b correspond to the level-shift resistor 18 illustrated in FIG. 1. As illustrated in FIG. 5, the level shifters 17a and 17b and the level-shift resistors 18a and 18b are provided in the first substrate 1. The second substrate 2 is provided with pads 49a, 49b, 50a, and 50b.

One end of the level-shift resistor 18a is electrically connected to a drain electrode D of the level shifter 17a. The drain electrode D of the level shifter 17a and the level-shift resistor 18a may be electrically connected to each other via a metal wire (not illustrated). A source electrode S of the level shifter 17a is electrically connected to the pad 49a via a metal wire 96a. A gate electrode G of the level shifter 17a is electrically connected to the pad 50a via a metal wire 97a.

One end of the level-shift resistor 18b is electrically connected to a drain electrode D of the level shifter 17b. The drain electrode D of the level shifter 17b and the level-shift resistor 18b may be electrically connected to each other via a metal wire (not illustrated). A source electrode S of the level shifter 17b is electrically connected to the pad 49b via a metal wire 96b. A gate electrode G of the level shifter 17b is electrically connected to the pad 50b via a metal wire 97b.

### Comparative Example

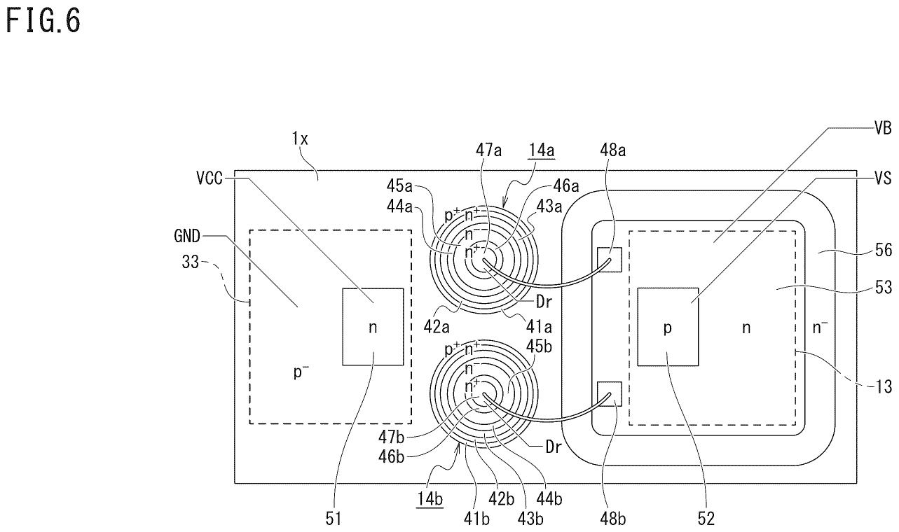

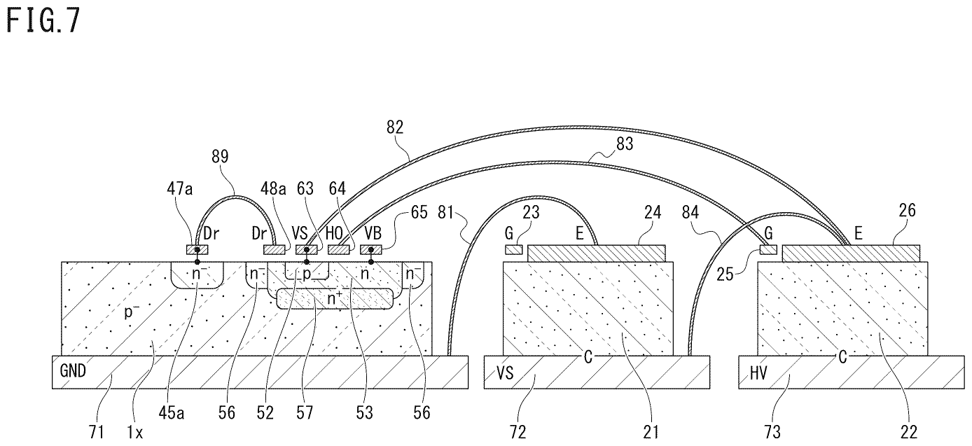

A semiconductor device of a comparative example is described below. FIG. 6 is a planar layout of a semiconductor substrate 1x of the semiconductor device of the comparative example, and FIG. 7 is a cross-sectional view illustrating the semiconductor substrate 1x of the semiconductor device of the comparative example and further the low-potential side switching element 21 and the high-potential side switching element 22. As illustrated in FIG. 6 and FIG. 7, the semiconductor device of the comparative example differs from the semiconductor device according to the first embodiment illustrated in FIG. 2 in that the GND reference circuit 33 and the floating reference circuit 13 are provided in the single p⁻-type semiconductor substrate 1x.

The semiconductor substrate 1x is installed on the lead frame 71 to which the GND potential is applied. The n-type well region 51 is provided on the top surface side of the semiconductor substrate 1x. The VCC potential is applied to the well region 51. The GND reference circuit 33 is provided in a part of the semiconductor substrate 1x and the well region 51.

The n-type well region 53 having a higher impurity concentration than the semiconductor substrate 1x is provided on the top surface side of the semiconductor substrate 1x. The VB potential is applied to the well region 53. The p-type well region 52 is provided on the top surface side of the well region 53. The VS potential is applied to the well region 52. The floating reference circuit 13 is provided in the well region 52 and the well region 53.

A voltage blocking region 56 of n⁻-type having a lower impurity concentration than the well region 53 is provided on the outer circumference side of the well region 53. A p-n junction between the voltage blocking region 56 and the semiconductor substrate 1x implements a high voltage diode, which is referred to as a high voltage junction termination (HVJT). The provision of the HVJT enables a normal operation regardless of whether the potential of the floating reference circuit 13 is led to be higher than the potential of the GND reference circuit 33 by several hundreds of volts. A buried region 57 of n⁺-type having a higher impurity concentration than the well region 53 is buried at a bottom of the well region 53.

The semiconductor device of the comparative example is provided with a parasitic pnp bipolar transistor implemented by the p-type well region 52 applied with the VS potential, the n-type well region 53 applied with the VB potential, and the p⁻-type semiconductor substrate 1x applied with the GND potential. A large amount of current flows if the parasitic pnp bipolar transistor operates because of an influence of noise when the VS potential is high, which would cause damage or wrong operations. To deal with this, the buried region 57 having a high impurity concentration is provided at the bottom of the well region 53 so as to suppress the operation of the parasitic pnp bipolar transistor. However, this configuration inevitably increases the number of the manufacturing steps because of the formation of the buried region 57, increasing the substrate cost and the process cost.

In contrast, the configuration of the semiconductor device according to the first embodiment, in which the GND reference circuit 33 and the floating reference circuit 13 are provided separately in the first substrate 1 and the second substrate 2, does not need the provision of the HVJT for electrically isolating the GND reference circuit 33 and the floating reference circuit 13 from each other, so as to avoid the provision of the vertical parasitic pnp bipolar transistor and thus suppress damage or wrong operations derived from the parasitic pnp bipolar transistor. This configuration also does not need to provide any buried region for suppressing the operation of the parasitic pnp bipolar transistor, so as to avoid the increase in the number of the manufacturing process including the step of forming such a buried region and the increase in the entire costs. In addition, the elimination of the provision of the HVJT can decrease the entire chip area accordingly.

Further, the semiconductor device according to the first embodiment has the configuration in which the first substrate 1 and the second substrate 2 are provided on the common lead frame 71. This configuration can expand the flexibility of design of the pattern for the lead frame 71, and also expand the flexibility of arrangement of the first substrate 1 and the second substrate 2 on the lead frame 71, as compared with the case in which the first substrate 1 and the second substrate 2 are provided on different lead frames.

Further, the semiconductor device according to the first embodiment has the configuration in which the second substrate 2 is isolated from the lead frame 71 by the insulating material 3. This configuration can avoid an increase in cost as compared with a case of providing the second substrate 2 with a SOI substrate for the isolation from the lead frame 71. Further, this configuration can expand the flexibility of choice of the material used for the insulating material 3 as compared with the use of the SOI substrate.

### Second Embodiment

A planar layout of a semiconductor device according to a second embodiment is common to that of the semiconductor device according to the first embodiment illustrated in FIG. 2. In particular, the semiconductor device according to the second embodiment includes the first substrate 1 provided with the GND reference circuit 33 and with the level shifter 14 of the level-up circuit 31. The second substrate 2 is provided with the level-shift resistor 15 of the level-up circuit 31 and with the floating reference circuit 13.

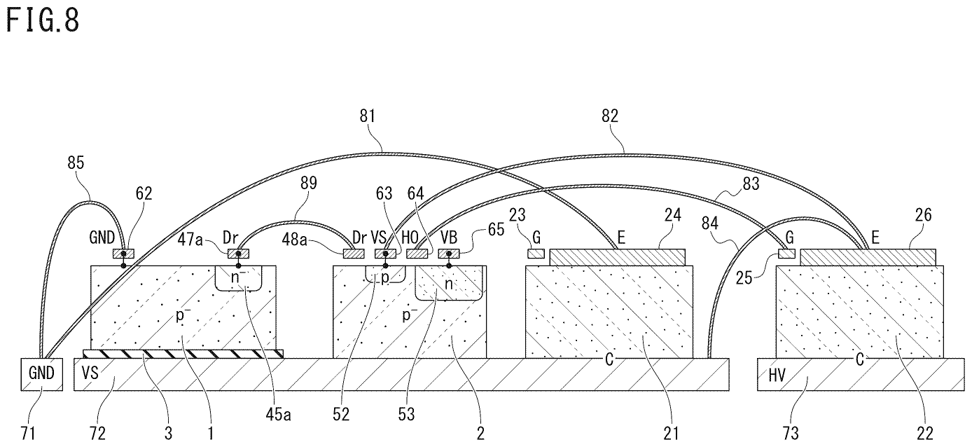

FIG. 8 is a cross-sectional view illustrating the semiconductor device according to the second embodiment, corresponding to the cross section of the semiconductor device according to the first embodiment illustrated in FIG. 4. As illustrated in FIG. 8, the semiconductor device according to the second embodiment differs from the semiconductor device according to the first embodiment in that the first substrate 1 and the second substrate 2 are provided on the common lead frame 72 to which the VS potential is applied.

The first substrate 1 is provided on the lead frame 72 with the insulating material 3 interposed. The first substrate 1 may be bonded to the lead frame 72 by use of the insulating material 3. The first substrate 1 and the lead frame 72 are insulated by the insulating material 3. The bottom surface side of the first substrate 1 may be provided with an electrode so as to be in contact with the insulating material 3. The insulating material 3 is epoxy resin paste or a die attach film (a DAF sheet). The GND electrode 62 on the top surface side of the first substrate 1 is electrically connected to the lead frame 71 applied with the GND potential via a metal wire 85. The first substrate 1 is thus fixed to the GND potential.

The second substrate 2 may be electrically connected to the lead frame 72 so as to be fixed to the VS potential. The bottom surface of the second substrate 2 may be provided on the lead frame 72 via a conductive adhesive. The bottom surface side of the second substrate 2 may be provided with an electrode so as to be provided on the lead frame 72 via conductive material such as solder, sinter material such as silver paste, or a conductive adhesive. The second substrate 2 may be provided on the lead frame 72 via an insulating material similar to the insulating material 3. The other configurations of the semiconductor device according to the second embodiment are substantially the same as those of the semiconductor device according to the first embodiment, and overlapping explanations are not repeated below.

The configuration of the semiconductor device according to the second embodiment, in which the GND reference circuit 33 and the floating reference circuit 13 are provided separately in the first substrate 1 and the second substrate 2, does not need the provision of the HVJT for electrically isolating the GND reference circuit 33 and the floating reference circuit 13 from each other, so as to avoid the provision of the vertical parasitic pnp bipolar transistor and thus suppress damage or wrong operations derived from the parasitic pnp bipolar transistor. This configuration also does not need to provide any buried region for suppressing the operation of the parasitic pnp bipolar transistor, so as to avoid the increase in the number of the manufacturing process including the step of forming such a buried region and the increase in the entire costs. In addition, the elimination of the provision of the HVJT can decrease the entire chip area accordingly.

Further, the semiconductor device according to the second embodiment has the configuration in which the first substrate 1 and the second substrate 2 are provided on the common lead frame 72. This configuration can expand the flexibility of design of the pattern for the lead frame 72, and also expand the flexibility of arrangement of the first substrate 1 and the second substrate 2 on the lead frame 72, as compared with the case in which the first substrate 1 and the second substrate 2 are provided on different lead frames.

Further, the semiconductor device according to the second embodiment has the configuration in which the first substrate 1 is isolated from the lead frame 72 by the insulating material 3. This configuration can avoid an increase in cost as compared with a case of providing the first substrate 1 with a SOI substrate for the isolation from the lead frame 72.

### Third Embodiment

### Circuit of Semiconductor Device

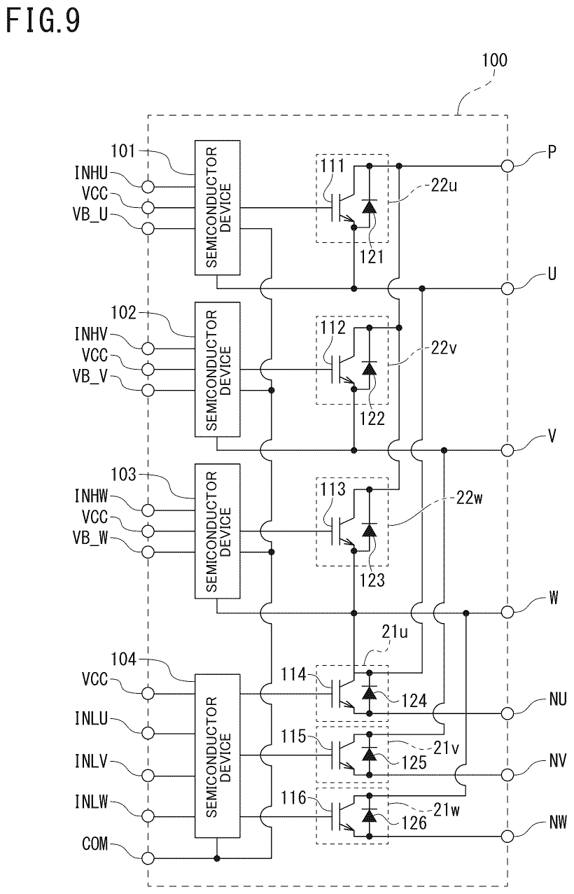

A semiconductor device according to a third embodiment is illustrated below with a configuration of including HVICs and switching elements for three phases. As illustrated in FIG. 9, the semiconductor device 100 according to the third embodiment includes semiconductor devices 101 to 104, switching elements 111 to 113 on a high-potential side (high-potential side switching elements), switching elements 114 to 116 on a low-potential side (low-potential side switching elements), and free-wheeling diodes (FWDs) 121 to 126.

The semiconductor devices 101 to 103 are each an HVIC. Comparing the configuration of the HVIC 10 illustrated in FIG. 1, the semiconductor devices 101 to 103 each include a part of the GND reference circuit 33, the floating reference circuit 13, and the level-shift circuit (31, 32). “A part of the GND reference circuit 33” will be described. Since the drive circuit 12 illustrated in FIG. 1 is a circuit for driving the switching element 21, the semiconductor devices 101 to 103 do not include the drive circuit 12. The control circuit 11 of the GND reference circuit 33 illustrated in FIG. 1 is a common configuration for the switching element (low-potential side switching element) 21 and the switching element (high-potential side switching element) 22, but the semiconductor devices 101 to 103 only need to include a circuit for controlling the high-potential side switching elements 111 to 113. Therefore, the semiconductor devices 101 to 103 only need to include a part of the control circuit 11 of the GND reference circuit 33 illustrated in FIG. 1. Hereinafter, the term “GND reference circuit 33” also includes a configuration in which the GND reference circuit 33 illustrated in FIG. 1 includes only a part of the control circuit 11. The respective semiconductor devices 101 to 103 include the level-up circuit 31, but do not necessarily include the level-down circuit 32.

The semiconductor device 101 outputs a signal for driving the high-potential side switching element 111 to a gate of the high-potential side switching element 111. Terminals INHU, VCC, VB_U, COM, and U are connected to the semiconductor device 101. The semiconductor device 102 outputs a signal for driving the high-potential side switching element 112 to a gate of the high-potential side switching element 112. Terminals INHV, VCC, VB_V, COM, and V are connected to the semiconductor device 102. The semiconductor device 103 outputs a signal for driving the high-potential side switching element 113 to a gate of the high-potential side switching element 113. Terminals INHW, VCC, VB_W, COM, and W are connected to the semiconductor device 103.

An input signal from an external microcomputer (not illustrated) is input to the respective terminals INHU, INHV, and INHW. The GND potential is applied to the common terminal COM connected to the respective semiconductor devices 101 to 103. The VCC potential is applied to the terminal VCC connected to the respective semiconductor devices 101 to 103. The VB potential is applied to the terminals VB_U, VB_V and VB_W respectively connected to the respective semiconductor devices 101 to 103.

The semiconductor device 104 is a low-voltage integrated circuit (LVIC). The semiconductor device 104 outputs signals for driving the low-potential side switching elements 114 to 116 to the respective gates of the low-potential side switching elements 114 to 116. Terminals INLU, INLV, INLW, VCC, and, COM are connected to the semiconductor device 104. Input signals from the external microcomputer (not illustrated) are input to the respective terminals INLU, INLV, and INLW. The VCC potential is applied to the terminal VCC connected to the semiconductor device 104.

The high-potential side switching elements 111 to 113 and the low-potential side switching elements 114 to 116 are each an insulated-gate bipolar transistor (IGBT), for example. The high-potential side switching elements 111 to 113 and the low-potential side switching elements 114 to 116 may each be any other switching element such as a MOSFET.

The respective collectors of the high-potential side switching elements 111 to 113 are connected to the terminal P. A HV potential is applied to the terminal P. An emitter of the high-potential side switching element 111 is connected to the terminal U. An emitter of the high-potential side switching element 112 is connected to the terminal V. An emitter of the high-potential side switching element 113 is connected to the terminal W. Output signals from the respective terminals U, V, and W are output to an external load.

A collector of the low-potential side switching element 114 is connected to the terminal U. An emitter of the low-potential side switching element 114 is connected to a terminal NU. A collector of the low-potential side switching element 115 is connected to the terminal V. An emitter of the low-potential side switching element 115 is connected to a terminal NV. A collector of the low-potential side switching element 116 is connected to the terminal W. An emitter of the low-potential side switching element 116 is connected to a terminal NW.

The free-wheeling diodes 121 to 123 are connected in antiparallel to the high-potential side switching elements 111 to 113. The free-wheeling diodes 124 to 126 are connected in antiparallel to the low-potential side switching elements 114 to 116.

As schematically indicated by the broken lines in FIG. 9, the high-potential side switching element 111 and the free-wheeling diode 121 are provided in a semiconductor chip 22u. The high-potential side switching element 112 and the free-wheeling diode 122 are provided in a semiconductor chip 22v. The high-potential side switching element 113 and the free-wheeling diode 123 are provided in a semiconductor chip 22w. The low-potential side switching element 114 and the free-wheeling diode 124 are provided in a semiconductor chip 21u. The low-potential side switching element 115 and the free-wheeling diode 125 are provided in a semiconductor chip 21v. The low-potential side switching element 116 and the free-wheeling diode 126 are provided in a semiconductor chip 21w. The semiconductor chips 21u, 21v, 21w, 22u, 22v, and 22w are each a reverse conducting IGBT.

### Configuration of Semiconductor Device

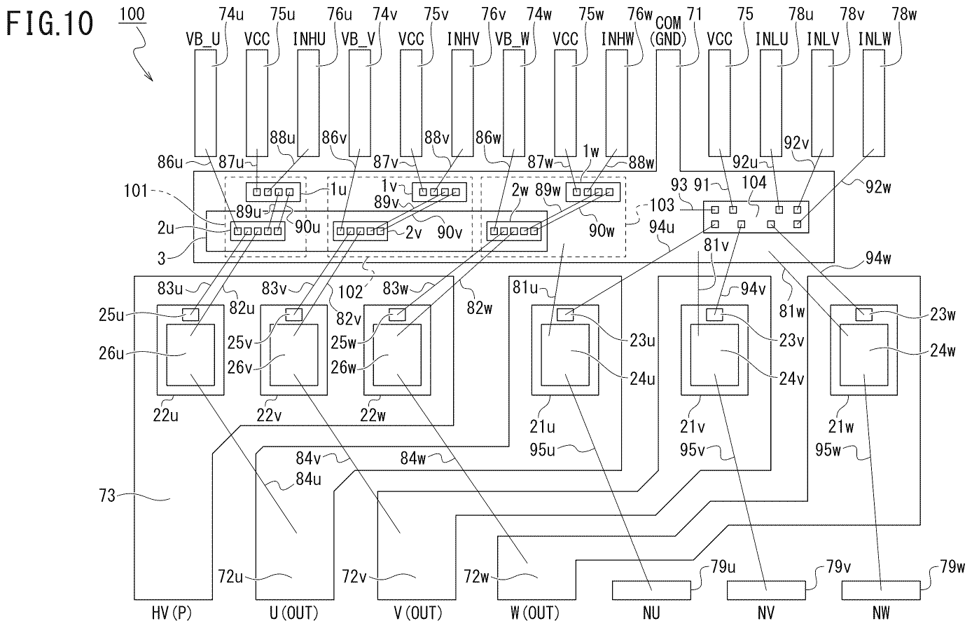

FIG. 10 illustrates an example of an installation configuration of the semiconductor device 100 according to the third embodiment. The semiconductor device 100 according to the third embodiment includes lead frames 74u, 75u, 76u, 74v, 75v, 76v, 74w, 75w, 76w, 71, 75, 78u, 78v, and 78w, as illustrated from the left to the right on the upper side in the sheet of FIG. 10. The lead frames 74u, 75u, 76u, 74v, 75v, 76v, 74w, 75w, 76w, 71, 75, 78u, 78v, and 78w each include conductive material such as aluminum and copper, for example.

The lead frames 74u, 74v, and 74w illustrated in FIG. 10 correspond to the respective terminals VB_U, VB_V and VB_W of the U-phase, the V-phase, and the W-phase illustrated in FIG. 9. The lead frames 75u, 75v, and 75w illustrated in FIG. 10 correspond to the respective terminals VCC of the U-phase, the V-phase, and the W-phase illustrated in FIG. 9. The lead frame 75 illustrated in FIG. 10 corresponds to the terminal VCC connected to the semiconductor device 104 illustrated in FIG. 9. The lead frames 76u, 76v, and 76w illustrated in FIG. 10 respectively correspond to the terminals INHU, INHV, and INHW illustrated in FIG. 9. The lead frame 71 illustrated in FIG. 10 corresponds to the terminal COM illustrated in FIG. 9. The lead frames 78u, 78v, and 78w illustrated in FIG. 10 respectively correspond to the terminals INLU, INLV, and INLW illustrated in FIG. 9.

Further, as illustrated from the left to the right on the lower side in the sheet of FIG. 10, the semiconductor device 100 according to the third embodiment includes lead frames 73, 72u, 72v, 72w, 79u, 79v, and 79w. The lead frames 73, 72u, 72v, 72w, 79u, 79v, and 79w each include conductive material such as aluminum and copper, for example.

The lead frame 73 illustrated in FIG. 10 corresponds to the terminal P illustrated in FIG. 9. The lead frames 72u, 72v, and 72w illustrated in FIG. 10 respectively correspond to the terminals U, V, and W illustrated in FIG. 9. The lead frames 79u, 79v, and 79w illustrated in FIG. 10 respectively correspond to the terminals NU, NV, and NW illustrated in FIG. 9.

A die pad of the lead frame 71 is provided between the respective lead frames 74u, 75u, 76u, 74v, 75v, 76v, 74w, 75w, 76w, 75, 78u, 78v, and 78w on the upper side in FIG. 10 and the respective lead frames 73, 72u, 72v, 72w, 79u, 79v, and 79w on the lower side in FIG. 10.

First substrates (semiconductor chips) 1u, 1v, and 1w, second substrates (semiconductor chips) 2u, 2v, and 2w, and the semiconductor chip (the semiconductor device) 104 are provided on the die pad of the lead frame 71. The first substrates 1u, 1v, and 1w and the second substrates 2u, 2v, and 2w are arranged adjacent to each other on the common lead frame 71.

As schematically indicated by the broken lines in FIG. 10, the first substrate 1u and the second substrate 2u implement the semiconductor device 101, corresponding to the semiconductor device 101 illustrated in FIG. 9. The first substrate 1v and the second substrate 2v implement the semiconductor device 102, corresponding to the semiconductor device 102 illustrated in FIG. 9. The first substrate 1w and the second substrate 2w implement the semiconductor device 103, corresponding to the semiconductor device 103 illustrated in FIG. 9. The semiconductor chip 104 corresponds to the semiconductor device 104 illustrated in FIG. 9.

The respective first substrates 1u, 1v, and 1w have the configuration similar to that of the first substrate 1 illustrated in FIG. 2 to FIG. 4. In particular, the respective first substrates 1u, 1v, and 1w are provided with the GND reference circuit 33, and the level shifter 14 of the level-up circuit 31.

The first substrate 1u is electrically connected to the lead frame 75u via a metal wire 87u, and is electrically connected to the lead frame 76u via a metal wire 88u. The rear surface of the first substrate 1u is electrically connected to the lead frame 71. The first substrate 1v is electrically connected to the lead frame 75v via a metal wire 87v, and is electrically connected to the lead frame 76v via a metal wire 88v. The rear surface of the first substrate 1v is electrically connected to the lead frame 71. The first substrate 1w is electrically connected to the lead frame 75w via a metal wire 87w, and is electrically connected to the lead frame 76w via a metal wire 88w. The rear surface of the first substrate 1w is electrically connected to the lead frame 71.

The respective second substrates 2u, 2v, and 2w are provided on the die pad of the lead frame 71 with the insulating material 3 interposed. While FIG. 10 illustrates the case in which the respective second substrates 2u, 2v, and 2w are provided on the die pad of the lead frame 71 with the common insulating material 3 interposed, the second substrates 2u, 2v, and 2w may be provided on the die pad of the lead frame 71 independently of each other with different insulating materials interposed. The respective second substrates 2u, 2v, and 2w have the configuration common to that of the second substrate 2 illustrated in FIG. 2 and FIG. 4. In particular, the respective second substrates 2u, 2v, and 2w are provided with the level-shift resistor 15 of the level-up circuit 31, and the floating reference circuit 13.

The second substrate 2u is electrically connected to the lead frame 74u via a metal wire 86u, and is electrically connected to the first substrate 1u via metal wires 89u and 90u. The second substrate 2v is electrically connected to the lead frame 74v via a metal wire 86v, and is electrically connected to the first substrate 1v via metal wires 89v and 90v. The second substrate 2w is electrically connected to the lead frame 74w via a metal wire 86w, and is electrically connected to the first substrate 1w via metal wires 89w and 90w.

The semiconductor chip 104 is electrically connected to the lead frame 75 via a metal wire 91, electrically connected to the lead frame 78u via a metal wire 92u, electrically connected to the lead frame 78v via a metal wire 92v, electrically connected to the lead frame 78w via a metal wire 92w, and electrically connected to the lead frame 71 via a metal wire 93.

The semiconductor chips 22u, 22v, and 22w are provided on a die pad of the lead frame 73. The semiconductor chip 22u corresponds to the high-potential side switching element 111 and the free-wheeling diode 121 illustrated in FIG. 9. The semiconductor chip 22v corresponds to the high-potential side switching element 112 and the free-wheeling diode 122 illustrated in FIG. 9. The semiconductor chip 22w corresponds to the high-potential side switching element 113 and the free-wheeling diode 123 illustrated in FIG. 9.

A collector electrode (not illustrated) on the bottom surface side of the semiconductor chip 22u is electrically connected to the lead frame 73. A gate electrode 25u on the top surface side of the semiconductor chip 22u is electrically connected to the second substrate 2u via a metal wire 83u. An emitter electrode 26u on the top surface side of the semiconductor chip 22u is electrically connected to the second substrate 2u via a metal wire 82u, and is electrically connected to the lead frame 72u via a metal wire 84u.

A collector electrode (not illustrated) on the bottom surface side of the semiconductor chip 22v is electrically connected to the lead frame 73. A gate electrode 25v on the top surface side of the semiconductor chip 22v is electrically connected to the second substrate 2v via a metal wire 83v. An emitter electrode 26v on the top surface side of the semiconductor chip 22v is electrically connected to the second substrate 2v via a metal wire 82v, and is electrically connected to the lead frame 72v via a metal wire 84v.

A collector electrode (not illustrated) on the bottom surface side of the semiconductor chip 22w is electrically connected to the lead frame 73. A gate electrode 25w on the top surface side of the semiconductor chip 22w is electrically connected to the second substrate 2w via a metal wire 83w. An emitter electrode 26w on the top surface side of the semiconductor chip 22w is electrically connected to the second substrate 2w via a metal wire 82w, and is electrically connected to the lead frame 72w via a metal wire 84w.

The semiconductor chip 21u is provided on a die pad of the lead frame 72u. The semiconductor chip 21u corresponds to the low-potential side switching element 114 and the free-wheeling diode 124 illustrated in FIG. 9. A collector electrode (not illustrated) on the bottom surface side of the semiconductor chip 21u is electrically connected to the lead frame 72u. A gate electrode 23u on the top surface side of the semiconductor chip 21u is electrically connected to the semiconductor chip 104 via a metal wire 94u. An emitter electrode 24u on the top surface side of the semiconductor chip 21u is electrically connected to the lead frame 71 via a metal wire 81u, and is electrically connected to the lead frame 79u via a metal wire 95u.

The semiconductor chip 21v is provided on a die pad of the lead frame 72v. The semiconductor chip 21v corresponds to the low-potential side switching element 115 and the free-wheeling diode 125 illustrated in FIG. 9. A collector electrode (not illustrated) on the bottom surface side of the semiconductor chip 21v is electrically connected to the lead frame 72v. A gate electrode 23v on the top surface side of the semiconductor chip 21v is electrically connected to the semiconductor chip 104 via a metal wire 94v. An emitter electrode 24v on the top surface side of the semiconductor chip 21v is electrically connected to the lead frame 71 via a metal wire 81v, and is electrically connected to the lead frame 79v via a metal wire 95v.

The semiconductor chip 21w is provided on a die pad of the lead frame 72w. The semiconductor chip 21w corresponds to the low-potential side switching element 116 and the free-wheeling diode 126 illustrated in FIG. 9. A collector electrode (not illustrated) on the bottom surface side of the semiconductor chip 21w is electrically connected to the lead frame 72w. A gate electrode 23w on the top surface side of the semiconductor chip 21w is electrically connected to the semiconductor chip 104 via a metal wire 94w. An emitter electrode 24w on the top surface side of the semiconductor chip 21w is electrically connected to the lead frame 71 via a metal wire 81w, and is electrically connected to the lead frame 79w via a metal wire 95w.

The configuration of the semiconductor device 100 according to the third embodiment, in which the GND reference circuit 33 and the floating reference circuit 13 are provided separately in the first substrates 1u, 1v, and 1w and the second substrates 2u, 2v, and 2w in the respective semiconductor devices 101 to 103 for the three phases, does not need the provision of the HVJT for electrically isolating the GND reference circuit 33 and the floating reference circuit 13 from each other, so as to avoid the provision of the vertical parasitic pnp bipolar transistor and thus suppress damage or wrong operations derived from the parasitic pnp bipolar transistor. This configuration also does not need to provide any buried region for suppressing the operation of the parasitic pnp bipolar transistor, so as to avoid the increase in the number of the manufacturing process including the step of forming such a buried region and the increase in the entire costs. In addition, the elimination of the provision of the HVJT can decrease the entire chip area accordingly.

Further, the semiconductor device according to the third embodiment has the configuration in which the first substrates 1u, 1v, and 1w and the second substrates 2u, 2v, and 2w are provided on the common lead frame 71. This configuration can expand the flexibility of design of the pattern for the lead frame 71, and also expand the flexibility of arrangement of the first substrates 1u, 1v, and 1w and the second substrates 2u, 2v, and 2w on the lead frame 71, as compared with a case in which the first substrates 1u, 1v, and 1w and the second substrates 2u, 2v, and 2w are provided on different lead frames.

Further, the semiconductor device 100 according to the third embodiment has the configuration in which the second substrates 2u, 2v, and 2w are isolated from the lead frame 71 by the insulating material 3. This configuration can avoid an increase in cost as compared with a case of providing the second substrates 2u, 2v, and 2w with a SOI substrate for the isolation from the lead frame 71.

### Fourth Embodiment

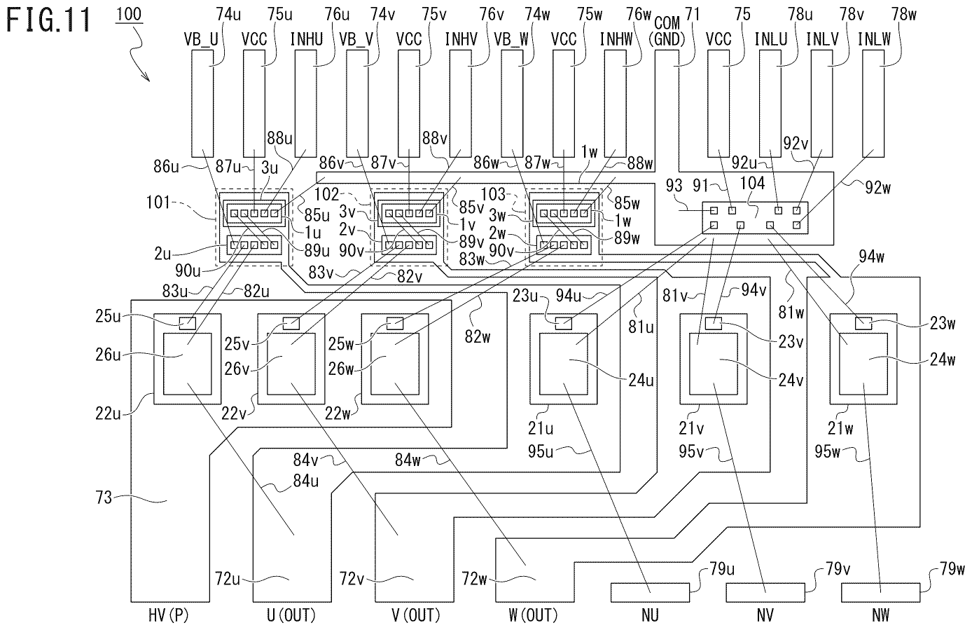

A semiconductor device according to a fourth embodiment has a circuit configuration similar to that of the semiconductor device 100 according to the third embodiment illustrated in FIG. 9. FIG. 11 illustrates an example of an installation configuration of the semiconductor device 100 according to the fourth embodiment. As illustrated in FIG. 11, the semiconductor device 100 according to the fourth embodiment differs from the semiconductor device according to the third embodiment illustrated in FIG. 10 in that the first substrates 1u, 1v, and 1w and the second substrates 2u, 2v, and 2w are provided respectively on the lead frames 72u, 72v, and 72w, instead of the common lead frame 71.

The semiconductor device according to the fourth embodiment has a configuration in which the lead frames 72u, 72v, and 72w further extend to reach the positions provided with the first substrates 1u, 1v, and 1w and the second substrates 2u, 2v, and 2w. The first substrate 1u and the second substrate 2u are arranged adjacent to each other. Similarly, the first substrate 1v and the second substrate 2v are arranged adjacent to each other, and the first substrate 1w and the second substrate 2w are arranged adjacent to each other.

The first substrate 1u and the second substrate 2u implementing the semiconductor device 101 are arranged on the common lead frame 72u. The first substrate 1u is provided on the lead frame 72u with insulating material 3u interposed. The first substrate 1u are electrically connected to the lead frame 71 via a metal wire 85u. The other electrical connectional relations regarding the first substrate 1u are common to those in the semiconductor device according to the third embodiment, and overlapping explanations are not repeated below. The rear surface of the second substrate 2u is electrically connected to the lead frame 72u. The other electrical connectional relations regarding the second substrate 2u are common to those in the semiconductor device according to the third embodiment, and overlapping explanations are not repeated below.

The first substrate 1v and the second substrate 2v implementing the semiconductor device 102 are arranged on the common lead frame 72v. The first substrate 1v is provided on the lead frame 72v with insulating material 3v interposed. The first substrate 1v are electrically connected to the lead frame 71 via a metal wire 85v. The other electrical connectional relations regarding the first substrate 1v are common to those in the semiconductor device according to the third embodiment, and overlapping explanations are not repeated below. The rear surface of the second substrate 2v is electrically connected to the lead frame 72v. The other electrical connectional relations regarding the second substrate 2v are common to those in the semiconductor device according to the third embodiment, and overlapping explanations are not repeated below.

The first substrate 1w and the second substrate 2w implementing the semiconductor device 103 are arranged on the common lead frame 72w. The first substrate 1w is provided on the lead frame 72w with insulating material 3w interposed. The first substrate 1w are electrically connected to the lead frame 71 via a metal wire 85w. The other electrical connectional relations regarding the first substrate 1w are common to those in the semiconductor device according to the third embodiment, and overlapping explanations are not repeated below. The rear surface of the second substrate 2w is electrically connected to the lead frame 72w. The other electrical connectional relations regarding the second substrate 2w are common to those in the semiconductor device according to the third embodiment, and overlapping explanations are not repeated below. The other configurations of the semiconductor device according to the fourth embodiment are substantially the same as those of the semiconductor device according to the third embodiment, and overlapping explanations are not repeated below.

The configuration of the semiconductor device 100 according to the fourth embodiment, in which the GND reference circuit 33 and the floating reference circuit 13 are provided separately in the first substrates 1u, 1v, and 1w, and the second substrates 2u, 2v, and 2w in the respective semiconductor devices 101 to 103 for the three phases, does not need the provision of the HVJT for electrically isolating the GND reference circuit 33 and the floating reference circuit 13 from each other, so as to avoid the provision of the vertical parasitic pnp bipolar transistor and thus suppress damage or wrong operations derived from the parasitic pnp bipolar transistor. This configuration also does not need to provide any buried region for suppressing the operation of the parasitic pnp bipolar transistor, so as to avoid the increase in the number of the manufacturing process including the step of forming such a buried region and the increase in the entire costs. In addition, the elimination of the provision of the HVJT can decrease the entire chip area accordingly.

Further, the semiconductor device according to the fourth embodiment has the configuration in which the first substrates 1u, 1v, and 1w and the second substrates 2u, 2v, and 2w are provided on the corresponding common lead frames 72u, 72v, and 72w. This configuration can expand the flexibility of design of the pattern for the lead frames 72u, 72v, and 72w, and also expand the flexibility of arrangement of the first substrates 1u, 1v, and 1w and the second substrates 2u, 2v, and 2w on the respective lead frames 72u, 72v, and 72w, as compared with a case in which the first substrates 1u, 1v, and 1w and the second substrates 2u, 2v, and 2w are provided on different lead frames.

Further, the semiconductor device 100 according to the fourth embodiment has the configuration in which the first substrates 1u, 1v, and 1w are isolated from the lead frames 72u, 72v, and 72w by the insulating materials 3u, 3v, and 3w. This configuration can avoid an increase in cost as compared with a case of providing the first substrates 1u, 1v, and 1w with a SOI substrate for the isolation from the lead frames 72u, 72v, and 72w.

### Fifth Embodiment

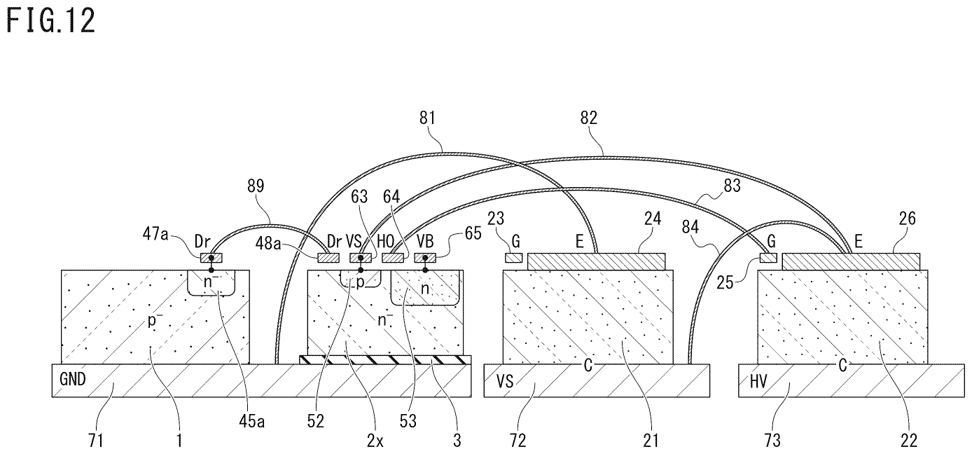

FIG. 12 is a cross-sectional view illustrating a semiconductor device according to a fifth embodiment, corresponding to the cross section of the semiconductor device according to the first embodiment illustrated in FIG. 4. The semiconductor device according to the fifth embodiment differs from the semiconductor device according to the first embodiment in that the conductivity of the second substrate 2x is n⁻-type opposite to that of the first substrate 1, as illustrated in FIG. 12. The other configurations of the semiconductor device according to the fifth embodiment are substantially the same as those of the semiconductor device according to the first embodiment, and overlapping explanations are not repeated below.

The configuration of the semiconductor device according to the fifth embodiment, in which the GND reference circuit 33 and the floating reference circuit 13 are provided separately in the first substrate 1 and the second substrate 2x, does not need the provision of the HVJT for electrically isolating the GND reference circuit 33 and the floating reference circuit 13 from each other, so as to avoid the provision of the vertical parasitic pnp bipolar transistor and thus suppress damage or wrong operations derived from the parasitic pnp bipolar transistor. This configuration also does not need to provide any buried region for suppressing the operation of the parasitic pnp bipolar transistor, so as to avoid the increase in the number of the manufacturing process including the step of forming such a buried region and the increase in the entire costs. In addition, the elimination of the provision of the HVJT can decrease the entire chip area accordingly.

Further, the semiconductor device according to the fifth embodiment has the configuration in which the first substrate 1 and the second substrate 2x are provided on the common lead frame 71. This configuration can expand the flexibility of design of the pattern for the lead frame 71, and also expand the flexibility of arrangement of the first substrate 1 and the second substrate 2x on the lead frame 71, as compared with the case in which the first substrate 1 and the second substrate 2x are provided on different lead frames.

Further, the semiconductor device according to the fifth embodiment has the configuration in which the second substrate 2x is isolated from the lead frame 71 by the insulating material 3. This configuration can avoid an increase in cost as compared with a case of providing the second substrate 2x with a SOI substrate for the isolation from the lead frame 71.

### Other Embodiments

As described above, the invention has been described according to the first to fifth embodiments, but it should not be understood that the description and drawings implementing a portion of this disclosure limit the invention. Various alternative embodiments of the present disclosure, examples, and operational techniques will be apparent to those skilled in the art from this disclosure.

For example, the respective configurations disclosed in the first to fifth embodiments can be combined together as appropriate without contradiction with each other. As described above, the invention includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

What is claimed is:

1. A semiconductor device comprising:
a GND reference circuit based on a GND potential and a floating reference circuit based on a potential higher than the GND potential;
a lead frame;
a first semiconductor substrate arranged on the lead frame and provided with the GND reference circuit; and
a second semiconductor substrate arranged on the lead frame and provided with the floating reference circuit,
wherein either the first semiconductor substrate or the second semiconductor substrate is arranged on the lead frame with an insulating material interposed.

2. The semiconductor device of claim 1, wherein the insulating material is epoxy resin paste or a die attach film.

3. The semiconductor device of claim 1, wherein the GND reference circuit and the floating reference circuit are electrically connected to each other via a level-shift circuit.

4. The semiconductor device of claim 3, wherein the level-shift circuit includes a level-up circuit including:
an n-channel MOSFET provided in the first semiconductor substrate; and
a first resistor provided in the second semiconductor substrate and connected to a drain of the n-channel MOSFET.

5. The semiconductor device of claim 4, wherein the drain of the n-channel MOSFET and the first resistor are electrically connected to each other via a metal wire.

6. The semiconductor device of claim 3, wherein the level-shift circuit includes a level-up circuit including:
two n-channel MOSFETs provided in the first semiconductor substrate; and
two first resistors provided in the second semiconductor substrate and respectively connected to drains of the n-channel MOSFETs.

7. The semiconductor device of claim 3, wherein the level-shift circuit includes a level-down circuit including:
a p-channel MOSFET provided in the first semiconductor substrate; and
a second resistor provided in the first semiconductor substrate and connected to a drain of the p-channel MOSFET.

8. The semiconductor device of claim 7, wherein the drain of the p-channel MOSFET and the second resistor are electrically connected to each other via a metal wire.

9. The semiconductor device of claim 3, wherein the level-shift circuit includes a level-down circuit including
two p-channel MOSFETs provided in the first semiconductor substrate, and
two second resistors provided in the first semiconductor substrate and respectively connected to drains of the p-channel MOSFETs.

10. The semiconductor device of claim 1, wherein:
the GND potential is applied to the lead frame; and
the second semiconductor substrate is arranged on the lead frame with the insulating material interposed.

11. The semiconductor device of claim 1, wherein:
a potential higher than the GND potential is applied to the lead frame; and
the first semiconductor substrate is arranged on the lead frame with the insulating material interposed.
